(19) United States
(12) Patent Application Publication
(10) Pub. No.: US 2026/0179208 A1
(43) Pub. Date: Jun. 25, 2026

(54) METHOD FOR OPERATING AN AERIAL IMAGE MEASURING SYSTEM AND SUCH AN AERIAL IMAGE MEASURING SYSTEM

(71) Applicant: Carl Zeiss SMT GmbH, Oberkochen (DE)

(72) Inventor: Renzo Capelli, Heidenheim (DE)

(21) Appl. No.: 19/428,799

(22) Filed: Dec. 22, 2025

(30) Foreign Application Priority Data
Dec. 23, 2024 (DE) 102024139602.4

(51) Int. Cl. G06T 7/00

(52) U.S. Cl. CPC G06T 7/0004; G06T 2207/10032; G06T 2207/30148

(57) ABSTRACT

A method for operating an aerial image measuring system for the qualification and/or measurement of an EUV mask, the aerial image measuring system comprising a vacuum chamber with a measuring process chamber and a process preparation chamber, an EUV plasma source, and a vacuum lock for transferring the EUV mask into the process preparation chamber, the method comprising parallel execution of preparation measures within the vacuum chamber and/or at or in the vacuum lock in order to prepare the qualification and/or measurement of the EUV mask; and qualifying and/or measuring the EUV mask by use of the aerial image measuring system by capturing an aerial image of the EUV mask.

### CROSS-REFERENCE TO RELATED APPLICATION

This application claims benefit under 35 U.S.C. §119 to German Patent Application 102024139 602.4, filed on December 23, 2024, the entire content of the above application is incorporated by reference.

### TECHNICAL FIELD

The present invention relates to a method for operating an aerial image measuring system for the qualification of an EUV mask (Extreme Ultraviolet Lithography) by use of the aerial image measuring system. Furthermore, the invention relates to an aerial image measuring system for the qualification of an EUV mask.

### BACKGROUND

Microlithography is used to produce microstructured components, such as for example integrated circuits. The microlithography process is carried out using a lithography apparatus having an illumination system and a projection system. The image of a mask (reticle) illuminated by use of the illumination system is projected here by use of the projection system onto a substrate, for example, a silicon wafer, which is coated with a light-sensitive layer (photoresist) and is arranged in the image plane of the projection system, in order to transfer the mask structure to the light-sensitive coating of the substrate.

Driven by the desire for ever smaller structures in the production of integrated circuits, EUV lithography apparatuses that use light at a wavelength in the range of 0.1 nm to 30 nm, in particular 13.5 nm, are currently under development. Since most materials absorb light at this wavelength, such EUV lithography apparatuses require the use of reflective optical units, i.e., mirrors, instead of refractive optical units, i.e., lens elements, as used previously. Furthermore, so-called EUV masks are required for the production of the fine structures on semiconductor wafers.

As the complexity of EUV masks increases, the precise qualification of these masks is becoming increasingly important in semiconductor production. For example, the qualification of EUV masks is intended to enable precise verification of mask errors and their potential effects on the lithographic process.

The mask metrology system for recording aerial images, which is also referred to as aerial image measuring system, uses metrology based on aerial images in order to provide a complete emulation of a scanner and thus to assess mask defects as far as possible under real production conditions. The mask metrology system for recording aerial images provides high-precision information on the printability of mask defects without the need for physical wafer prints. This enables quick and reliable inspection of masks and contributes to optimizing production processes. The measurements of the EUV mask take place within a vacuum chamber.

The mask metrology technology addresses both defect review and the verification of repairs to masks. With the aid of an EUV plasma source and high-precision positioning, a detailed characterization of mask defects is achieved in order to assess the influence thereof on the lithographic process. By providing an exact reproduction of the EUV printing behaviour and integrating automated image analyses, the mask metrology system for recording aerial images provides a basis for the manufacture of EUV masks which have the fewest possible defects and which are used in high-volume manufacturing processes.

One challenge for the known mask metrology technology for recording aerial images is the required measurement preparation times, which are orders of magnitude higher than the actual measurement time for measuring an EUV mask. For example, just providing a stably functioning EUV plasma source requires a ramp-up time of the order of magnitude of more than 30 minutes, with exposure time calibrations often being necessary. This ramp-up time must be regarded as unproductive time, since measurements with the mask metrology system for recording aerial images are not possible during this time.

Furthermore, in preparation for the measurement, the EUV mask is handled outside and within the mask metrology system for recording aerial images. In addition, for preparation, a suitable field stop aperture or aperture stop is inserted – and adjusted – into an optical unit of the mask metrology system for recording aerial images by use of a robotic arm located inside the vacuum chamber. Furthermore, the EUV mask is brought from outside via a vacuum lock into the vacuum chamber of the mask metrology system for recording aerial images by use of a robotic arm, the EUV mask being transferred to the robotic arm in the vacuum lock. Since the one robotic arm is also used for the handling of optical elements, this handling must first be completed in order to carry out the mask handling. The one robotic arm then brings the EUV mask inside the vacuum chamber onto a mask platform, on which the EUV mask is positioned highly accurately for measurement purposes. This entire preparation process is time-intensive and requires 40 minutes or more, for example, which contrasts with a measurement time of approximately 5 minutes per mask. This preparation process must be regarded as unproductive time, since measurements with the mask metrology system for recording aerial images are not possible during this time.

### SUMMARY

Against this background it is an aspect of the present invention to provide an improved method for operating an aerial image measuring system and/or an improved aerial image measuring system.

Accordingly, a method for operating an aerial image measuring system for the qualification and/or measurement of an EUV mask is proposed. The aerial image measuring system comprises a vacuum chamber with a measuring process chamber and a process preparation chamber, an EUV plasma source, which is arranged in the measuring process chamber, for example, and a vacuum lock for transferring the EUV mask into the process preparation chamber. The method comprises the following steps:

at least partially parallel execution of preparation measures within the vacuum chamber and/or at or in the vacuum lock in order to prepare the qualification and/or measurement of the EUV mask; and

qualifying and/or measuring the EUV mask by use of the aerial image measuring system by capturing an aerial image of the EUV mask.

According to a further aspect, an aerial image measuring system for the qualification and/or measurement of an EUV mask is proposed. The aerial image measuring system comprises a vacuum chamber with a measuring process chamber and a process preparation chamber, an EUV plasma source, a vacuum lock for transferring the EUV mask into the process preparation chamber, and a control device configured for the parallel execution of preparation measures within the vacuum chamber and/or at or in the vacuum lock in order to prepare the qualification and/or measurement of the EUV mask.

The vacuum chamber is preferably subdivided into at least two regions, namely a measuring process chamber and a process preparation chamber. The vacuum chamber preferably creates an environment with reduced pressure in order to minimize external influences such as particles and contaminants, which is crucial for carrying out the sensitive measuring processes for the measurement and qualification of the EUV mask.

The measuring process chamber is preferably provided for carrying out the measurements, while the process preparation chamber performs the preparation work on the EUV mask before the latter proceeds to the measurement.

An EUV plasma source is integrated in the measuring process chamber, and generates extreme ultraviolet light (EUV) having a very short wavelength. This EUV plasma source is important for the operation of the measuring system since it provides the necessary light for imaging and analysis of the EUV mask. On account of its positioning within the measuring process chamber, the EUV mask can be illuminated directly and without significant losses, which makes it possible to recognize extremely fine structures and defects on the masks.

A vacuum lock allows the EUV mask to be transferred from the external environment into the process preparation chamber of the vacuum chamber. For example, the vacuum lock can also be preceded by a load lock, which constitutes an interface between a human operator and the aerial image measuring system. The load lock can be part of a front-end module of the aerial image measuring system. The vacuum lock preferably preserves the integrity of the vacuum and prevents the ingress of air or contaminants while the mask is being transferred into the process preparation chamber.

This ensures that mask handling proceeds smoothly without adversely affecting the conditions inside the vacuum chamber. The described set-up enables clean and efficient preparation and execution of the measuring process and preferably ensures a precise analysis of EUV masks under optimal conditions.

The aerial image measuring system can be configured in such a way that in a load lock a protective gas atmosphere is already set in order in this way to introduce the EUV mask to be measured without a protective housing into the vacuum lock. The load lock can be arranged upstream of the vacuum lock, or the load lock can be part of the vacuum lock. For example, the protective gas atmosphere can be designed according to ISO-1. For example, the EUV mask can be brought from the load lock into the vacuum lock by use of a first robotic arm. In the vacuum lock, the EUV mask is preferably transferred to a second robotic arm. The second robotic arm can handle the EUV mask within the vacuum chamber, in particular bring the EUV mask from the process preparation chamber into the measuring process chamber, in which the measurement of the EUV mask takes place.

Alternatively, the aerial image measuring system can also be designed in such a way that the EUV mask, in particular via the load lock, is brought in a protective container into the vacuum lock. For example, the protective container is in turn arranged in an outer protective container. In the region of the load lock, the protective container together with the EUV mask is removed from the outer protective container, for example, by use of a first robotic arm arranged outside the vacuum chamber, and is introduced into the load lock. The protective container is then preferably brought by use of the first robotic arm from the load lock into the vacuum lock and transferred in the vacuum lock to a second robotic arm, which is arranged in the interior of the process preparation chamber. The second robotic arm can transfer the protective container, for example, to a protective container holder arranged in the process preparation chamber. The second robotic arm can preferably subsequently open the protective container in the protective container holder and remove the EUV mask from the protective container in order to handle the EUV mask within the vacuum chamber, in particular in order to bring the EUV mask from the process preparation chamber into the measuring process chamber, in which the measurement of the EUV mask takes place. The process for removing the mask from the protective container can preferably be monitored by an optical sensor, in particular a camera.

In particular, the invention describes the further development of the mask metrology system for recording aerial images for EUV qualification, which enables a precise analysis of the printable mask defects in less time. In particular, the preparation time can be considerably reduced by the present method, in particular by the parallelization of preparation measures. This enables more EUV masks to be measured in the same time. In some implementations, the system of this disclosure can measure the EUV masks in sequence one by one, with more EUV masks measured within a given amount of time compared to previous systems. This increases productivity in comparison with existing systems. The present method and measuring system reduce overhead costs and thus increase efficiency. In the present case, a plurality of preparation measures are preferably parallelized. Preferably, all preparation measures that can be executed simultaneously are parallelized. In this regard, for example, preparation measures performed with the first robotic arm can be executed simultaneously with preparation measures performed with the second robotic arm, if the preparation measures do not require an interaction between the first and the second robotic arms.

In a further aspect, it is proposed that the preparation measures within the vacuum chamber comprise switching on and/or operating the EUV plasma source for stabilizing the EUV plasma source.

For example, the EUV plasma source can be switched on in parallel with the handling of the EUV mask and/or further preparation measures, for example, in order to set the operating conditions (e.g., voltage and frequency) of the EUV plasma source.

In a further aspect, it is proposed that the aerial image measuring system furthermore comprises a storage device with optical elements, said storage device being arranged in the process preparation chamber, wherein the preparation measures within the vacuum chamber comprise bringing at least one of the optical elements between the storage device and the measuring process chamber and/or adjusting the at least one of the optical elements in the measuring process chamber.

The optical elements can be arranged in the storage device. The storage device can also have a plurality of holders, for example, for different types of optical elements. For example, the optical elements can be arranged in cassettes in the storage device. The storage device can preferably define parking spaces in which the optical elements are arranged or parked, if they are not required for the measurement of the EUV mask or for setting the illumination properties of the EUV plasma source.

For example, in order to parallelize the measurement preparation, the illumination conditions of the light generated by the EUV plasma source can be prepared by selecting and inserting optical elements. For example, as optical elements, field stop apertures and/or aperture stops can be introduced into a beam path of the EUV plasma source and/or stops already arranged in the beam path (for example, from a previous measurement) can be replaced. For example, the aperture stops can be sigma-NA stops (also referred to as sigma/NA stops). It is used to control the illumination properties of the optical system by defining the numerical aperture range (NA) and the sigma of the illumination.

In the present case, an optical element preferably defines a component which can be arranged within the beam path in order to be able to set different illumination and/or imaging properties of the EUV plasma source. The optical element can preferably also comprise a system with a plurality of optical elements. In this way, depending on the type of measurement, an optical element can preferably be selected and introduced into the beam path of the EUV plasma source by use of the second robotic arm.

This handling of the optical elements is done by use of the second robotic arm in the interior of the vacuum chamber. The handling of the optical elements can take place, for example, in parallel with the handling of the EUV mask in the region of the vacuum lock. The handling of the EUV mask in the region of the vacuum chamber serves, for example, for transferring the EUV mask via the vacuum lock into the vacuum chamber and is carried out by use of the first robotic arm.

In a further aspect, it is proposed that the preparation measures at or in the vacuum lock comprise providing the EUV mask at the vacuum lock and/or introducing the EUV mask into the vacuum lock and/or transferring the EUV mask through the vacuum lock into the process preparation chamber.

These mask handling processes can be carried out, for example, with the first robotic arm outside the vacuum chamber and/or with the first and second robotic arms in interaction within the vacuum lock and/or with the second robotic arm within the vacuum chamber. The handling of the EUV mask within the vacuum chamber can also comprise removing the EUV mask from a protective container. The handling of the EUV mask can also comprise the handling of the EUV mask arranged in the protective container, i.e., also the handling of the protective container.

In a further aspect, it is proposed that the preparation measures within the vacuum chamber comprises bringing the EUV mask from the process preparation chamber into the measuring process chamber and/or aligning the EUV mask on a mask platform provided in the measuring process chamber.

The controlled transfer of the EUV mask between the two chambers takes place within the vacuum environment. The process preparation chamber is used for preparation before the EUV mask is transferred into the measuring process chamber, in which the actual measurements take place. This transfer process is preferably precise and is carried out without interrupting the vacuum in order to avoid contaminations and to ensure a stable environment for the subsequent measurement. The handling process is preferably carried out by the second robotic arm.

The alignment of the EUV mask on a mask platform provided in the measuring process chamber preferably relates to the exact positioning of the EUV mask on a specific platform or holder located in the measuring process chamber. The mask platform preferably serves as a stable carrier that fixes the EUV mask during the measuring process. The exact alignment of the mask is crucial in order to ensure that the measurements can be carried out with high precision. The mask is preferably positioned in such a way that it is exactly at the focus of a measuring optical unit of the aerial image measuring system and has the correct orientation with respect to the EUV plasma source. This enables correct imaging and analysis of the mask structure. The measuring optical unit preferably comprises a plurality of optical elements, in particular mirrors and/or lens elements, and one or more optical elements and also an optical sensor for recording an aerial image of the EUV mask.

In a further aspect, it is proposed that switching on and/or operating the EUV plasma source comprises ramping up the EUV plasma source to predetermined operating conditions or operating the EUV plasma source at a reduced operating frequency compared to the predetermined operating conditions.

Especially in order not to adversely affect the consumables of the aerial image measuring system, the operating frequency of the plasma light source can initially also be reduced compared to the usual operating conditions. If the EUV plasma source is required later for a measurement, the operating frequency is ramped up to the operating conditions, although this requires less preparation time compared to a cold start of the EUV light source.

In a further aspect, it is proposed that the preparation measures within the vacuum chamber comprise opening and/or closing a flap or a door provided at the process preparation chamber and/or at the measuring process chamber and/or between the process preparation chamber and the measuring process chamber.

In order not to adversely affect consumables, furthermore, slides and/or doors of the vacuum chamber and to consumable filters can also be closed. Such consumable filters can be arranged, for example, between the process preparation chamber and the measuring process chamber. Consumables of an aerial image measuring system include, for example, components of the EUV plasma source such as electrodes or mirrors, optical components such as lens elements and filters that wear as a result of operation, vacuum seals such as O-rings, mask holders and fixings that become worn through repeated use, protective layers or filters for sensitive optical elements, cleaning materials for regular maintenance of the optical components and the vacuum chamber, vacuum pump oils and filters, and gas cylinders for the plasma processes.

Furthermore, a computer program product is proposed, which, on a program-controlled control device, causes an apparatus of the method elucidated above to be operated.

A computer program product, such as, e.g., a computer program means, can be provided or supplied for example as a storage medium, such as, e.g., a memory card, a USB stick, a CD-ROM, a DVD, or else in the form of a downloadable file from a server in a network. For example, in a wireless communications network, this can be effected by transferring an appropriate file comprising the computer program product or the computer program means.

Furthermore, a computer-readable (storage) medium is proposed, comprising instructions which, when executed by a computer, cause the latter to execute the method described above.

These instructions are preferably designed to cause a computer to execute the method described earlier. In this case, a specific method or algorithm that is implemented in the computer is executed. By way of example, the medium can be a hard disk, a CD-ROM, a USB stick or some other type of storage medium that stores the necessary instructions to cause the computer to execute the method.

"A” or “an” or “one” in the present case should not necessarily be understood as being restrictive to exactly one element. Rather, a plurality of elements, such as for example two, three or more, can also be provided. Nor should any other numeral used here be understood to the effect that there is a restriction to exactly the stated number of elements. Rather, unless indicated otherwise, numerical deviations upward and downward are possible.

The embodiments and features described for the method apply, mutatis mutandis, to the proposed aerial image measuring system, and vice versa.

Further possible implementations of the invention also encompass not explicitly mentioned combinations of features or embodiments that are described above or hereinafter with respect to the exemplary embodiments. A person skilled in the art will also add individual aspects as improvements or supplementations to the respective basic form of the invention.

Further advantageous configurations and aspects of the invention are the subject matter of the dependent claims and also of the exemplary embodiments of the invention that are described below. The invention is explained in greater detail hereinafter on the basis of preferred embodiments with reference to the appended figures.

### BRIEF DESCRIPTION OF DRAWINGS

FIG. 1 shows a schematic view of an aerial image measuring system in one embodiment;

FIG. 2 shows a schematic view of an aerial image measuring system in a further embodiment;

FIG. 3 shows a schematic view of a sequence diagram of parallelized preparation measures within such an aerial image measuring system; and

FIG. 4 shows a flowchart of one exemplary embodiment of the present method for operating an aerial image measuring system.

### DETAILED DESCRIPTION

In the figures, identical or functionally identical elements have been provided with the same reference signs, unless indicated otherwise. Furthermore, it should be noted that the illustrations in the figures are not necessarily true to scale.

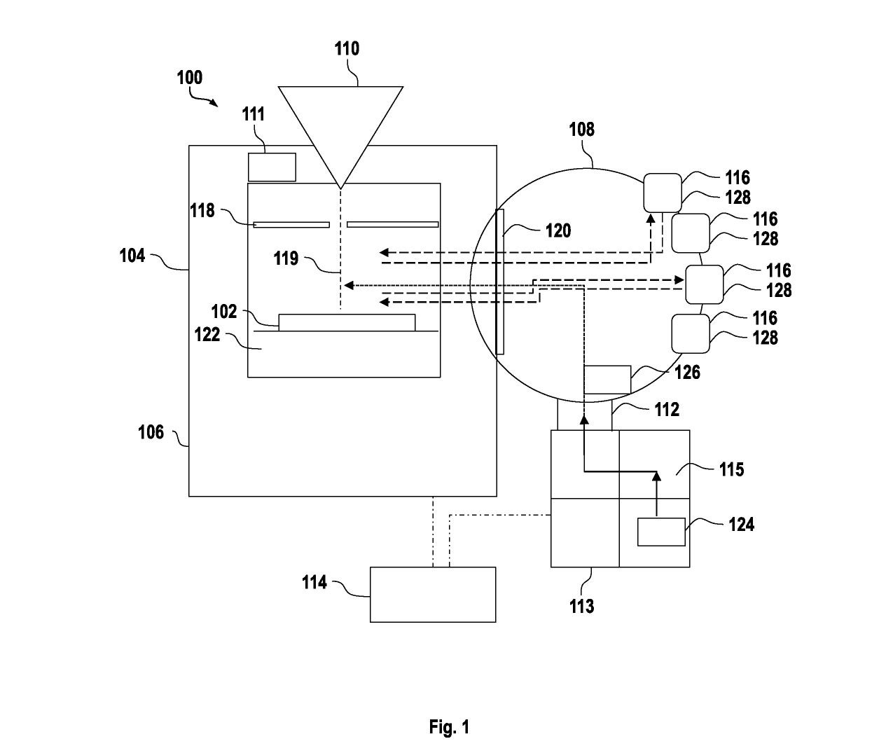

FIG. 1 shows an aerial image measuring system 100 according to one embodiment. The aerial image measuring system 100 is used for the qualification and/or measurement of an EUV mask 102. The aerial image measuring system 100 comprises a vacuum chamber 104 with a measuring process chamber 106 and a process preparation chamber 108. One or more vacuum pumps (not shown in the figure) can be used to maintain a low pressure environment in the vacuum chamber 104, including the measuring process chamber 106 and the process preparation chamber 108. Furthermore, the aerial image measuring system 100 comprises an EUV plasma source 110, which is arranged in the measuring process chamber 106 by way of example. The aerial image measuring system 100 likewise comprises a vacuum lock 112 for transferring the EUV mask 102 from a load lock 113 arranged upstream of the vacuum lock 112 into the process preparation chamber 108. The load lock 113 may comprise a load chamber between a first and a second cutoff valve, and a vacuum system for generating a protective gas atmosphere and/or vacuum in the load chamber. The second cutoff valve may connect the load chamber with the vacuum lock 112. The load lock 113 can already have a region in which a protective gas atmosphere 115 prevails. The aerial image measuring system 100 has a control device 114, which in the present case is configured for the parallel execution of preparation measures within the vacuum chamber 104 and/or at or in the vacuum lock 112 in order to prepare the qualification and/or measurement of the EUV mask 102. The qualification and/or measurement of the EUV mask 102 is carried out by recording an aerial image of the EUV mask 102 by use of an optical sensor 111, in particular a camera. The optical sensor 111 can include one or more arrays of individually addressable sensing elements or pixels (e.g., charge coupled device (CCD) or complementary metal oxide semiconductor (CMOS) sensing elements or pixels). The captured aerial image is then analyzed by an evaluation device, not shown in more specific detail, in order to qualify the EUV mask in this way. For example, the evaluation device may be implemented to qualify the EUV mask according to a predetermined classification or evaluation algorithm. The control device 114 can communicate with the various devices and components being controlled by wired and/or wireless communication links, using electrical and/or optical control and data signals.

The aerial image measuring system 100 furthermore comprises a storage device 116 with optical elements 118, said storage device being arranged in the process preparation chamber 108. In FIG. 1, one of the optical elements 118 is arranged in the measuring process chamber 106 in the beam path 119 of the EUV plasma source 110. The optical elements and/or the EUV plasma source may include aspects or elements as disclosed in US 2025/0298175 A1 in connection with an EUV collector. The entire content of US 2025/0298175 is incorporated by reference. The aerial image measuring system 100 furthermore comprises a flap or a door 120, which in the present case is provided between the process preparation chamber 108 and the measuring process chamber 106. In the measuring process chamber 106, a mask platform 122 is furthermore provided, on which the EUV mask 102 is arranged in order to be measured.

The aerial image measuring system 100 is thus configured in such a way that in the load lock 113 arranged upstream of the vacuum lock 112, the protective gas atmosphere 115 is already set in order in this way to introduce the EUV mask 102 to be measured without a protective housing into the vacuum lock 112. For example, the protective gas atmosphere 115 can be designed according to ISO-1. For example, the EUV mask 102 can be brought from the load lock 113 into the vacuum lock 112 by use of a first robotic arm 124.

In some implementations, the first robotic arm 124 includes a multi-axis manipulator including one or more rotary and/or linear actuators that provide precise positioning and orientation of the EUV mask 102 along multiple axes. The first robotic arm 124 can include an end-effector adapted for EUV mask handling. The end effector can include, e.g., edge-gripping mechanisms or vacuum clamping surfaces designed to securely hold the mask or its carrier during transport. The first robotic arm 124 can include high resolution position sensors and feedback control to ensure accurate alignment and placement of the EUV mask 102.

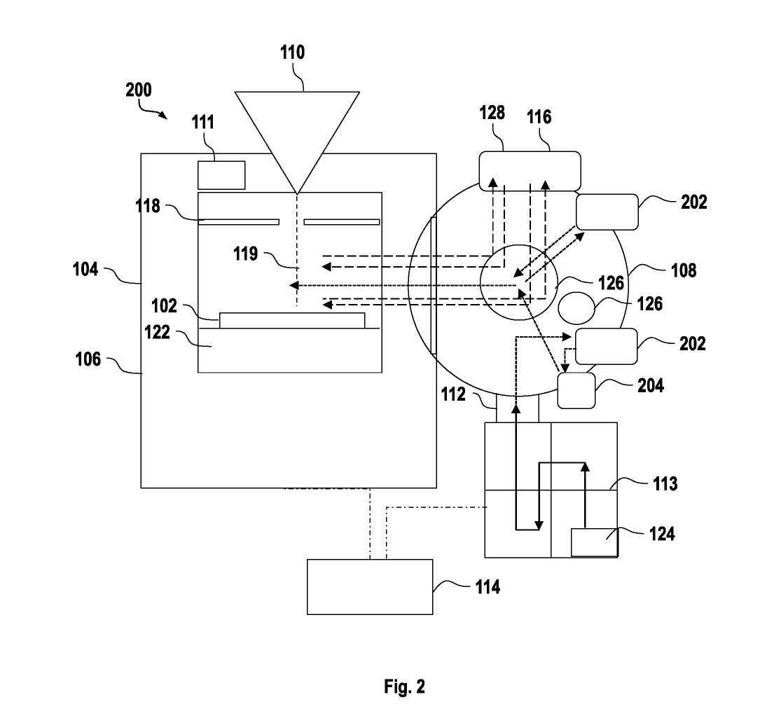

In the vacuum lock 112, the EUV mask 102 is transferred to a second robotic arm 126, which can have a design similar to the first robotic arm 124. The second robotic arm 126 can handle the EUV mask 102 within the vacuum chamber 104, in particular bring the EUV mask 102 from the process preparation chamber 108 into the measuring process chamber 106, in which the measurement of the EUV mask 102 takes place. It goes without saying that in the process preparation chamber 108 a plurality of second robotic arms 126 can also be provided, as shown by way of example in FIG. 2. In this regard, for example, it is possible to move and/or change more than one optical element 118 simultaneously. Furthermore, the second robotic arm 126 can align the EUV mask 102 on the mask platform 122 relative to the EUV plasma source 110 or the beam path 119 for the purpose of qualifying and/or measuring the EUV mask.

The optical elements 118 can be arranged in the storage device 116. The storage device 116 can comprise, for example, a plurality of holders 128, for example, for different types of optical elements 118. The handling of the optical elements 118 is done by use of the second robotic arm 126 in the interior of the vacuum chamber 104. The handling of the optical elements 118 can include, e.g., one or more of the following: adjusting positions and orientations of lenses and/or mirrors, sizes and positions of apertures, bringing new optical elements 118 from the storage device 116 to the interior of the vacuum chamber 104, bringing worn out and/or damaged optical elements 118 from the interior of the vacuum chamber 104 to the storage device 116, etc. The handling of the optical elements 118 can take place, for example, in parallel with the handling of the EUV mask 102 by use of the first robotic arm 124 in the region of the vacuum lock 113. The handling of the EUV mask 102 in the region of the vacuum chamber 104 serves for transferring the EUV mask 102 via the vacuum lock 112 into the vacuum chamber 104.

FIG. 2 shows an aerial image measuring system 200 according to a further embodiment. The aerial image measuring system 200 is designed in such a way that the EUV mask 102 is brought via the load lock 113, in a protective container (not shown), into the vacuum lock 112. For example, the protective container is in turn arranged in an outer protective container (not shown). In the region of the load lock 112, the protective container together with the EUV mask is removed from the outer protective container, for example, by use of the first robotic arm 124 arranged outside the vacuum chamber 104, and is introduced into the load lock 113. The (inner) protective container is then preferably brought by use of the first robotic arm 124 from the load lock 113 into the vacuum lock 112 and transferred in the vacuum lock 112 to a second robotic arm 126, which is arranged in the interior of the process preparation chamber 108. The second robotic arm 126 can transfer the (inner) protective container, for example, to a protective container holder 202 arranged in the process preparation chamber 126. The second robotic arm 126 can preferably subsequently open the (inner) protective container in the protective container holder 202 and remove the EUV mask from the protective container in order to handle the EUV mask 102 within the vacuum chamber 104, in particular in order to bring the EUV mask 102 from the process preparation chamber 108 into the measuring process chamber 106, in which the measurement of the EUV mask 102 takes place. The process for removing the EUV mask 102 from the protective container can be monitored by an optical sensor 204, in particular a camera.

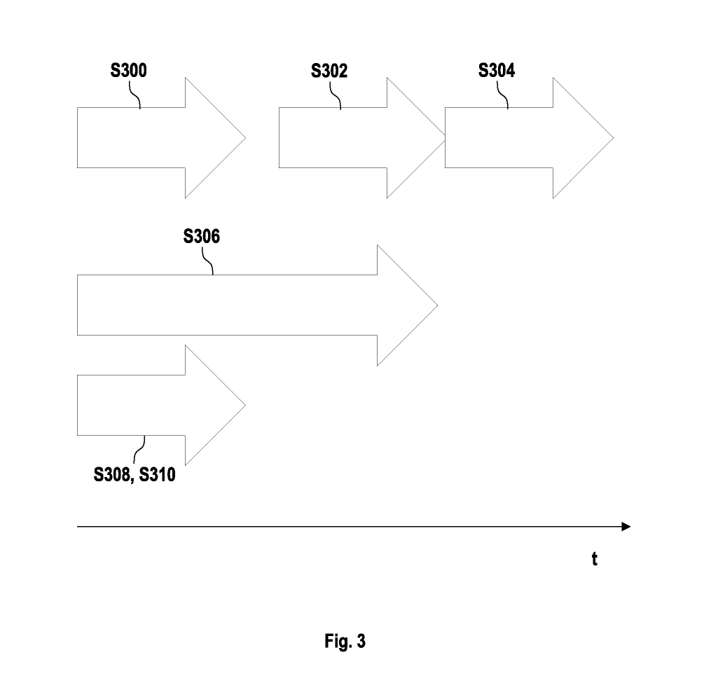

FIG. 3 shows a sequence diagram of parallelized preparation measures. In this case, with the aerial image measuring system 100, 200, for example, the handling S300 of the EUV mask 102 outside the vacuum chamber 104, as observed in the temporal progression t, is executed before the handling S302 of the EUV mask 102 inside the vacuum chamber 104. The recording S304 of an aerial image of the EUV mask 102 then subsequently takes place. In parallel with the handlings S300, S302 of the EUV mask 102 outside and within the vacuum chamber 104, the preparation measure executed in parallel in the present case involves switching on and/or operating S306 the EUV plasma source 110 for stabilizing the EUV plasma source 110. This can also involve ramping up the EUV plasma source 110 to predetermined operating conditions or operating the EUV plasma source 110 at a reduced operating frequency (e.g., reduced pulse repetition rate) compared to the predetermined operating conditions. In this case, the switching on and/or operating S306 is timed so that the EUV plasma source 110 is fully operational before the recording S304 of the aerial image of the EUV mask 102 takes place. Furthermore, for further parallelization of the preparation measures, what takes place at the same time as the handling S300 of the EUV mask 102 by use of the first robotic arm 124 outside the vacuum chamber 104 is a process of bringing S308 at least one of the optical elements 118 between the storage device 116 and the measuring process chamber 106 and/or adjusting S310 the at least one of the optical elements 118 in the measuring process chamber 106. Examples of adjusting the at least one of the optical elements 118 in the measuring process chamber 106 include adjusting positions and orientations of lenses and/or mirrors, sizes and positions of apertures, etc. Bringing S308 and/or adjusting S310 the optical element 118 preferably takes place only for as long as the second robotic arm 126 is required for the handling S302 of the EUV mask 102 within the vacuum chamber 104.

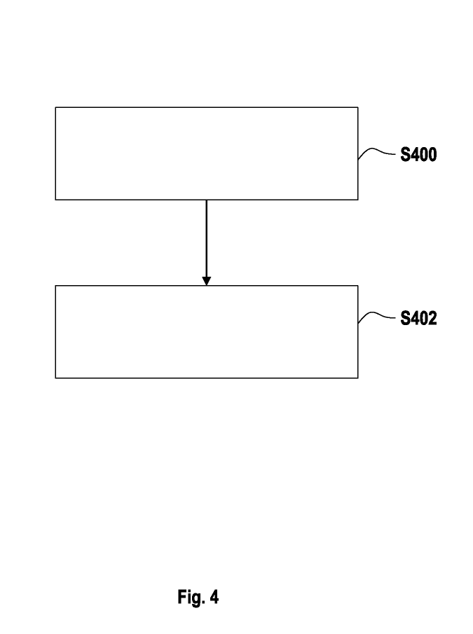

FIG. 4 shows a schematic flowchart of one exemplary embodiment of the present method. In this case, a step S400 involves at least partially parallel execution of preparation measures within the vacuum chamber 104 and/or at or in the vacuum lock 112 in order to prepare the qualification and/or measurement of the EUV mask 102. A step S402 involves qualifying and/or measuring the EUV mask 102 by use of the aerial image measuring system 100, 200 by capturing an aerial image of the EUV mask 102, for example, by use of the optical sensor 111.

In some implementations, each of the control device 114 and the evaluation device for analyzing the captured aerial image can include one or more programmable processors executing one or more computer programs to perform the functions described in this document. A computer program can be written in any form of programming language, including compiled or interpreted languages, and it can be deployed in any form, including as a stand-alone program or as a module, component, subroutine, or other unit suitable for use in a computing environment.

For example, each of the control device 104 and the evaluation device can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of the control device 104 can include one or more processors for executing instructions and one or more storage area devices for storing instructions and data. Generally, the control device 104 and/or the evaluation device will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, and flash storage devices; magnetic disks, e.g., internal hard disks or removable disks; magneto-optical disks; and CD-ROM, DVD-ROM, and/or Blu-ray discs.

In some implementations, the processes that involve processing of data (e.g., analyzing aerial images) can be implemented using software for execution on one or more mobile computing devices, one or more local computing devices, and/or one or more remote computing devices. For instance, the software forms procedures in one or more computer programs that execute on one or more programmed or programmable computer systems, either in the mobile computing devices, local computing devices, or remote computing systems (which may be of various architectures such as distributed, client/server, or grid), each including at least one processor, at least one data storage system (including volatile and non-volatile memory and/or storage elements), at least one wired or wireless input device or port, and at least one wired or wireless output device or port.

In some implementations, the software may be provided on a medium, such as a CD-ROM, DVD-ROM, Blu-ray disc, solid state drive, or hard disk drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

Although the present invention has been described on the basis of exemplary embodiments, it is modifiable in diverse ways.

### LIST OF REFERENCE SIGNS

100 Aerial image measuring system

102 EUV mask

104 Vacuum chamber

106 Measuring process chamber

108 Process preparation chamber

110 EUV plasma source

111 Optical sensor

112 Vacuum lock

113 Load lock

114 Control device

115 Protective gas atmosphere

116 Storage device

118 Optical elements

119 Beam path

120 Door

122 Mask platform

124 First robotic arm

126 Second robotic arm

128 Holder

200 Aerial image measuring system

202 Protective container holder

204 Optical sensor

S300 Handling

S302 Handling

S304 Recording

S306 Switching on and/or operating

S308 Bringing

S310 Adjusting

S400 Parallel execution

S402 Qualifying and/or measuring

t Temporal progression

What is claimed is:

1. A method for operating an aerial image measuring system for the qualification and/or measurement of an EUV mask, the aerial image measuring system comprising a vacuum chamber with a measuring process chamber and a process preparation chamber, an EUV plasma source, and a vacuum lock for transferring the EUV mask into the process preparation chamber, the method comprising
parallel execution of preparation measures within the vacuum chamber and/or at or in the vacuum lock in order to prepare the qualification and/or measurement of the EUV mask; and
qualifying and/or measuring the EUV mask by use of the aerial image measuring system by capturing an aerial image of the EUV mask.

2. The method of claim 1, wherein the preparation measures within the vacuum chamber comprise switching on and/or operating the EUV plasma source for stabilizing the EUV plasma source.

3. The method of claim 1, wherein the aerial image measuring system furthermore comprises a storage device with optical elements, said storage device being arranged in the process preparation chamber, wherein the preparation measures within the vacuum chamber comprise bringing at least one of the optical elements between the storage device and the measuring process chamber and/or adjusting the at least one of the optical elements in the measuring process chamber.

4. The method of claim 1, wherein the preparation measures at or in the vacuum lock comprise providing the EUV mask at the vacuum lock and/or introducing the EUV mask into the vacuum lock and/or transferring the EUV mask through the vacuum lock into the process preparation chamber.

5. The method of claim 1, wherein the preparation measures within the vacuum chamber comprise bringing the EUV mask from the process preparation chamber into the measuring process chamber and/or aligning the EUV mask on a mask platform provided in the measuring process chamber.

6. The method of claim 2, wherein switching on and/or operating the EUV plasma source comprises ramping up the EUV plasma source to predetermined operating conditions or operating the EUV plasma source at a reduced operating frequency compared to the predetermined operating conditions.

7. The method of claim 1, wherein the preparation measures within the vacuum chamber comprise opening and/or closing a flap or a door provided at the process preparation chamber and/or at the measuring process chamber and/or between the process preparation chamber and the measuring process chamber.

8. An aerial image measuring system for the qualification and/or measurement of an EUV mask, the aerial image measuring system comprising a vacuum chamber with a measuring process chamber and a process preparation chamber, an EUV plasma source and a vacuum lock for transferring the EUV mask into the process preparation chamber, and a control device configured for the parallel execution of preparation measures within the vacuum chamber and/or at or in the vacuum lock in order to prepare the qualification and/or measurement of the EUV mask.

9. A computer program product, comprising instructions which, when the program is executed by a computer, cause the latter to execute the steps of the method of claim 1.

10. The computer program product of claim 9, comprising instructions which, when the program is executed by the computer, cause the latter to execute the steps of the method of claim 2.

11. The computer program product of claim 9, comprising instructions which, when the program is executed by the computer, cause the latter to execute the steps of the method of claim 3.

12. The computer program product of claim 9, comprising instructions which, when the program is executed by the computer, cause the latter to execute the steps of the method of claim 4.

13. The computer program product of claim 9, wherein the preparation measures at or in the vacuum lock comprise providing the EUV mask at the vacuum lock and/or introducing the EUV mask into the vacuum lock and/or transferring the EUV mask through the vacuum lock into the process preparation chamber.

14. The aerial image measuring system of claim 8, wherein the control device is configured to control the aerial image measuring system to qualify and/or measure the EUV mask by capturing an aerial image of the EUV mask.

15. The aerial image measuring system of claim 8, wherein the control device is configured to perform parallel execution of the preparation measures within the vacuum chamber including switching on and/or operating the EUV plasma source for stabilizing the EUV plasma source.

16. The aerial image measuring system of claim 8, wherein the aerial image measuring system comprises a storage device with optical elements, the storage device being arranged in the process preparation chamber, wherein the control device is configured to perform parallel execution of the preparation measures within the vacuum chamber including bringing at least one of the optical elements between the storage device and the measuring process chamber and/or adjusting the at least one of the optical elements in the measuring process chamber.

17. The aerial image measuring system of claim 8, wherein the control device is configured to perform parallel execution of the preparation measures at or in the vacuum lock including providing the EUV mask at the vacuum lock and/or introducing the EUV mask into the vacuum lock and/or transferring the EUV mask through the vacuum lock into the process preparation chamber.

18. The aerial image measuring system of claim 8, wherein the control device is configured to perform parallel execution of the preparation measures within the vacuum chamber including bringing the EUV mask from the process preparation chamber into the measuring process chamber and/or aligning the EUV mask on a mask platform provided in the measuring process chamber.

19. The aerial image measuring system of claim 15, wherein switching on and/or operating the EUV plasma source comprises ramping up the EUV plasma source to predetermined operating conditions or operating the EUV plasma source at a reduced operating frequency compared to the predetermined operating conditions.

20. The aerial image measuring system of claim 8, wherein the control device is configured to perform parallel execution of the preparation measures within the vacuum chamber including opening and/or closing a flap or a door provided at the process preparation chamber and/or at the measuring process chamber and/or between the process preparation chamber and the measuring process chamber.
